(19) United States
(12) Patent Application Publication
(10) Pub. No.: US 2022/0416028 A1
(43) Pub. Date: Dec. 29, 2022

(54) VERTICAL FIELD EFFECT TRANSISTOR AND METHOD FOR THE FORMATION THEREOF

(71) Applicant: Robert Bosch GmbH, Stuttgart (DE)

(72) Inventors: Jens Baringhaus, Sindelfingen (DE); Daniel Krebs, Aufhausen (DE); Dick Scholten, Stuttgart (DE)

(21) Appl. No.: 17/762,993

(22) PCT Filed: Sep. 21, 2020
(86) PCT No.: PCT/EP2020/076293

§ 371 Date: Mar. 23, 2022

(30) Foreign Application Priority Data
Oct. 21, 2019 (DE) 10 2019 216 138.3

(51) Int. Cl. H01L 29/08; H01L 29/10; H01L 29/78; H01L 29/66

(52) U.S. Cl. CPC H01L 29/0847; H01L 29/1041; H01L 29/7827; H01L 29/785; H01L 29/1095; H01L 29/66795

(57) ABSTRACT

A vertical field effect transistor. The vertical field effect transistor includes: a drift area including a first conductivity type; a semiconductor fin on or above the drift area, a source/drain electrode on or above the drift area; and a shielding structure, which is situated laterally adjacent to the at least one side wall of the semiconductor fin in the drift area, the shielding structure including a second conductivity type, which differs from the first conductivity type, and the semiconductor fin being electrically conductively connected to the source/drain electrode.

### FIELD

The present invention relates to a vertical field effect transistor and a method for the formation thereof.

### BACKGROUND INFORMATION

In conventional transistors (for example MOSFETs or MISFETs), the actively switchable components are provided by an inversion channel, for example, by the p-area in an npn-transition, in which an electron path is formed by applying a gate voltage. For the application of semiconductors including a wide band gap (for example silicon carbide (SiC) or gallium nitride (GaN)) in power electronics, the use of so-called power FinFETs (Fin=fin, FET=field effect transistor) may be advantageous. The structure of a conventional power FinFET 100 is illustrated in FIG. 1. Moreover, doping profile 120 and electrical field 140 at 600 V drain voltage of this structure are shown in FIG. 1 with lateral and vertical dimensions 150 and 160 in μm. Conventional power FinFET 100 includes a drift area 110 including an n doping 114, a drain electrode 112, a source electrode 102, a gate electrode 108, a semiconductor fin 104, and an insulation 106. Semiconductor fin 104 is connected with the aid of an n+ doping 116 to source electrode 102. In power FinFET 100, the switchable component is made up of narrow semiconductor fin 104, which is switchable due to its geometry and matching selection of gate metallization 108. The channel resistance of power FinFET 100 is significantly less than in a conventional MOSFET or MISFET based on SiC or GaN. A lower on-resistance of the entire component results therefrom. Conventional power FinFET 100 does not have shielding of the channel area from electrical fields, as occur in particular in lockout mode. Accordingly, the achievable breakdown voltage is limited and is in particular highly dependent on process variations (for example, etching depth). In the right image in FIG. 1, the simulation of electrical field 140 in lockout mode is shown with an applied drain voltage of 600 V for a conventional FinFET 100. Highest field load 142 is to be found in insulation 106 below gate electrode 108.

### SUMMARY

An object of the present invention is to provide a vertical field effect transistor and a method for its manufacture, which provides a vertical field effect transistor having a higher electric strength and reliability. The object may be achieved according to one aspect of the present invention by a vertical field effect transistor. In accordance with an example embodiment of the present invention, the vertical field effect transistor includes: a drift area including a first conductivity type; a semiconductor fin on or above the drift area, a source/drain electrode being formed on or above the drift area laterally adjacent to at least one side wall of the semiconductor fin; and a shielding structure, which is situated laterally adjacent to the at least one side wall of the semiconductor fin in the drift area, the shielding structure including a second conductivity type, which differs from the first conductivity type. The semiconductor fin is electrically conductively connected to the source/drain electrode.

The shielding structure inside the drift area causes a change of the field distribution. The electrical field is increased at the p-n transitions of the vertical field effect transistor and thus decreases in the insulation underneath the gate metal. With the aid of the shielding structure, the electrical field may be reduced in particular in lockout mode in the insulation and displaced into the drift area. This enables the maximum field peaks reached to be reduced. A field effect transistor having higher electric strength and reliability may thus be provided.

The object may also achieved according to a further aspect of the present invention by a vertical field effect transistor. In accordance with an example embodiment of the present invention, the vertical field effect transistor includes: a drift area including a first conductivity type; a first semiconductor fin on or above the drift area; and a second semiconductor fin which is situated laterally adjacent to the first semiconductor fin on or above the drift area, a source/drain electrode being formed on or above the drift area laterally adjacent to at least one side wall of the first semiconductor fin; and a shielding structure, which is situated laterally adjacent to the at least one side wall of the first semiconductor fin; the shielding structure being situated in the second semiconductor fin; and the shielding structure including a second conductivity type, which differs from the first conductivity type, and the semiconductor fin being electrically conductively connected to the source/drain electrode.

The object may also be achieved according to a further aspect of the present invention by a method for forming a vertical field effect transistor. In accordance with an example embodiment of the present invention, the method includes: forming a drift area including a first conductivity type; forming a semiconductor fin on or above the drift area, a source/drain electrode being formed on or above the drift area laterally adjacent to at least one side wall of the semiconductor fin; and forming a shielding structure, which is situated laterally adjacent to the at least one side wall of the semiconductor fin in the drift area, the shielding structure including a second conductivity type, which differs from the first conductivity type, and the semiconductor fin being electrically conductively connected to the source/drain electrode.

Refinements of the aspects of the present invention are disclosed herein. Specific embodiments of the present invention are illustrated in the figures and are explained in greater detail hereinafter.

### BRIEF DESCRIPTION OF THE DRAWINGS

FIG. 1 shows sectional representations of a transistor structure of the related art.

FIGS. 2A and 2B show schematic sectional representations of a vertical field effect transistor according to various specific embodiments of the present invention.

FIGS. 3A through 3K show schematic sectional representations of a vertical field effect transistor according to various specific embodiments of the present invention.

FIG. 4 shows a flowchart of a method for designing a vertical field effect transistor according to various specific embodiments.

### DETAILED DESCRIPTION OF EXAMPLE EMBODIMENTS

In the detailed description below, reference is made to the figures, which form a part of this description and in which specific exemplary embodiments are shown for illustration, in which the present invention may be implemented. Other exemplary embodiments may be used and structural or logical modifications may be carried out without departing from the scope of protection of the present invention. The features of the various exemplary embodiments described herein may be combined with one another if not specifically indicated otherwise. The following detailed description is therefore not to be interpreted restrictively. In the figures, identical or similar elements are provided with identical reference numerals, if appropriate.

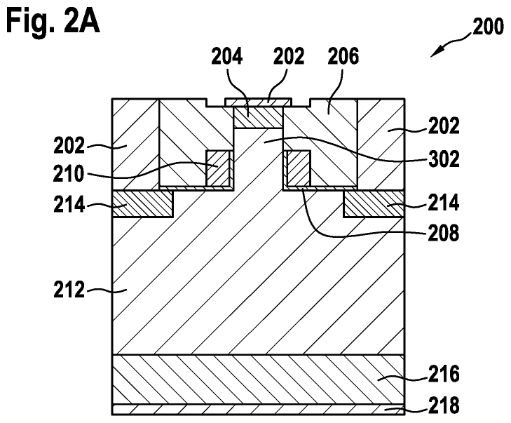

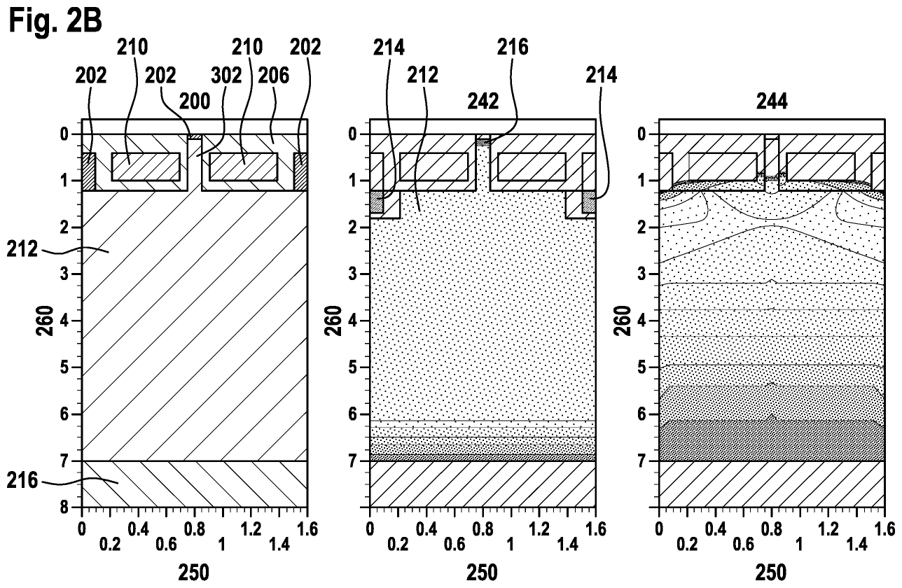

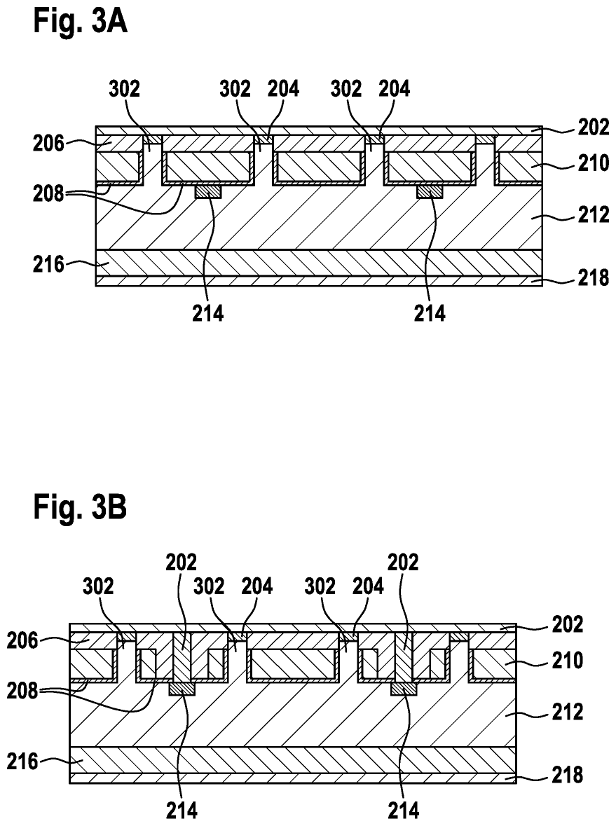

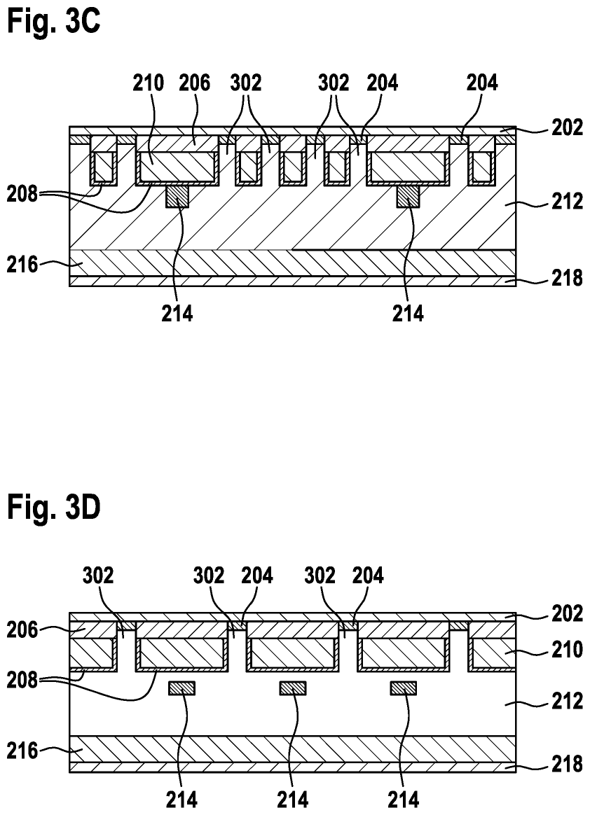

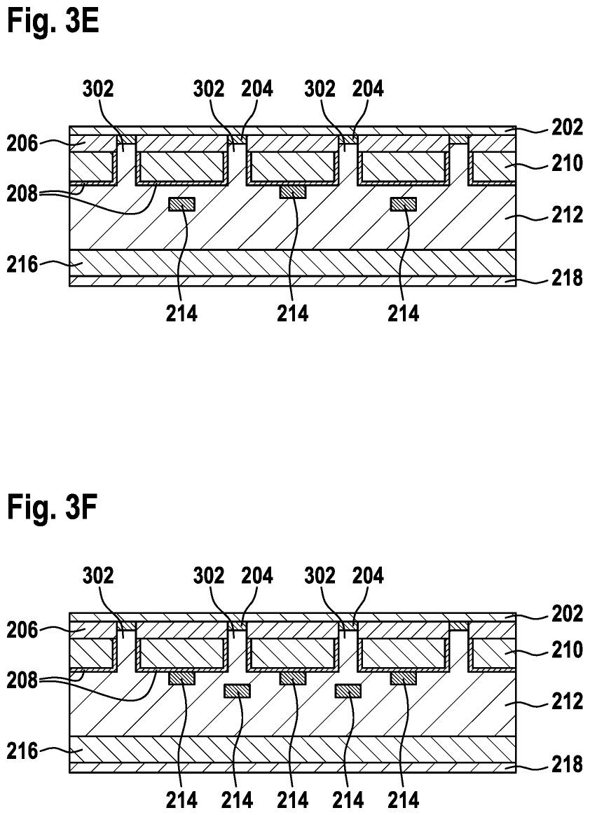

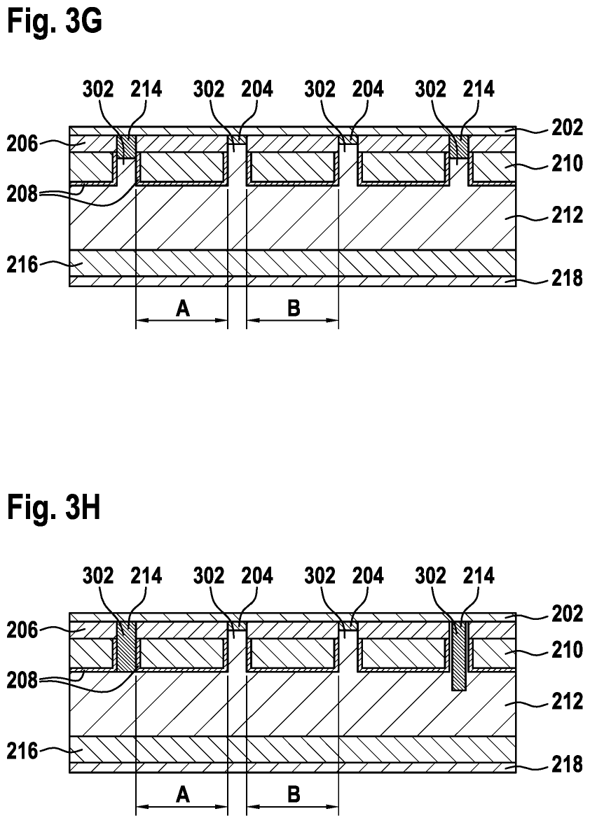

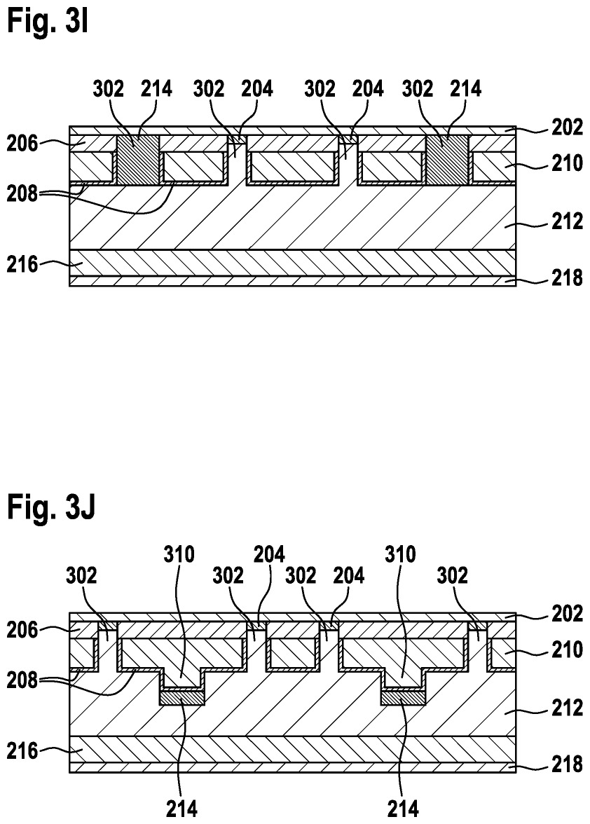

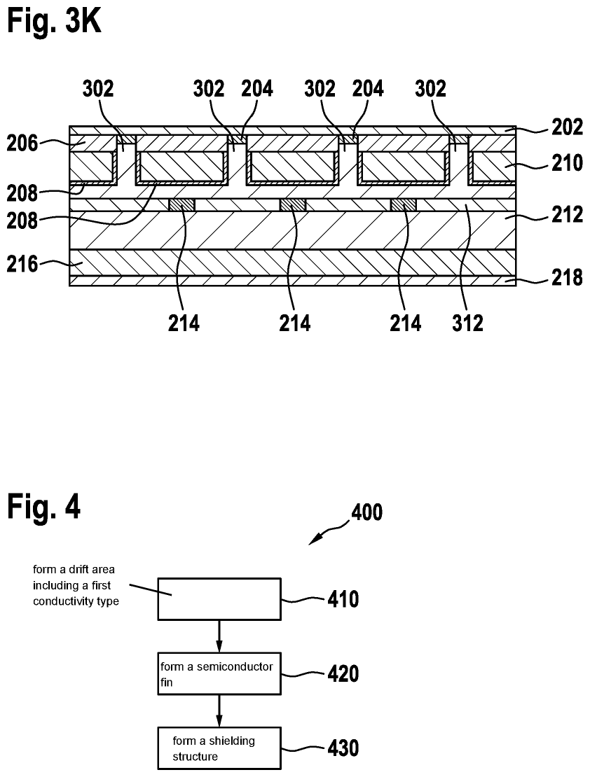

FIGS. 2A, B and FIGS. 3A through 3K show views of a vertical field effect transistor 200 according to various specific embodiments. FIG. 2A shows a specific embodiment in which a p-doped shielding structure 214 is formed laterally adjacent to a side wall of one or each semiconductor fin 302 in drift area 212.

In various specific embodiments, a vertical field effect transistor 200 includes a drift area 212 on a semiconductor substrate 216; a semiconductor fin 302 (the longitudinal direction of which extends perpendicularly to the plane of the drawing) on or above drift area 212, a shielding structure 214, a first source/drain electrode (for example, a source electrode 202), a second source/drain electrode (for example, a drain electrode 218). It is assumed by way of example hereinafter that first source/drain electrode 202 is a source electrode and second source/drain electrode 218 is a drain electrode. Vertical field effect transistor 200 furthermore includes a gate electrode 210 adjacent to at least one side wall of semiconductor fin 302, gate electrode 210 being electrically insulated with the aid of an insulation 206 from source electrode 202. A gate dielectric 208 is situated between gate electrode 210 and semiconductor fin 302. A highly-doped connection area 204 may electrically conductively connect semiconductor fin 302 to source electrode 202. Source electrode 202 may additionally be formed laterally adjacent to at least one side wall of semiconductor fin 302 on or above drift area 212. Shielding structure 214 is situated laterally adjacent to the at least one side wall of semiconductor fin 302 in drift area 212. Shielding structure 214 includes a second conductivity type which differs from the first conductivity type.

Semiconductor substrate 216 may be, for example, a GaN substrate 216 or a SiC substrate 216. Weakly n-conductive semiconductor drift area 212 (also referred to as drift zone 212) may be formed (for example applied) on semiconductor substrate 216, for example, a GaN or SiC drift area 212. Above drift area 212, an n-conductive semiconductor area may be formed in the form of semiconductor fin 302, for example, in the form of a GaN or SiC fin 302. An n+-conductive connection area 204 may be formed on semiconductor fin 302 or in an upper subsection of fin 302, with the aid of which source electrode 202 is contacted. Source electrode 202 may contact both shielding structure 214 and semiconductor fin 302. Drain electrode 218 may be located on the rear side of substrate 216.

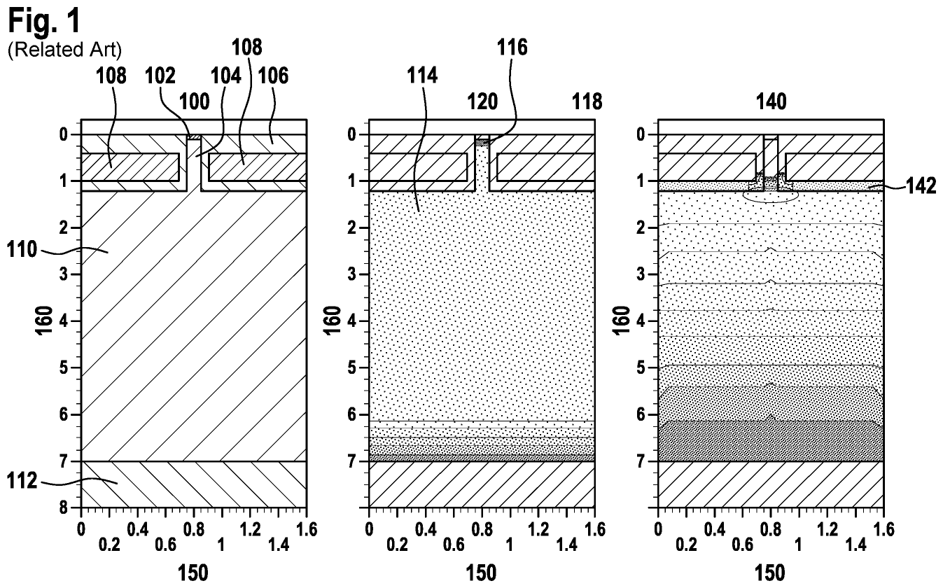

With the aid of the introduction of shielding structure 214, for example, in the form of highly doped p-GaN or p-SiC areas in drift area 212, shielding the base of semiconductor fin 302 (the area between semiconductor fin 302 and drift area 212) is made possible. A space charge region may be formed during operation between the areas of shielding structure 214 and drift area 212. The area in which a current may flow may thus be reduced, due to which the resistance may be increased. Due to the introduction of shielding structure 214, the overall resistance of field effect transistor 200 is increased in comparison to the variant without shielding structure (FIG. 1), as shown in FIG. 2B. FIG. 2B shows doping profile 242 and electrical field 244 at 600 V drain voltage of this structure 214 including lateral and vertical dimensions 250 and 260 in μm. In right image 244 in FIG. 2B, the simulation of electrical field 140 in lockout mode at an applied drain voltage of 600 V is shown. The field load below gate electrode 210 is reduced with the aid of shielding structure 214. The potential applied in case of lockout at drain electrode 218 results in an electrical field which has its maximum directly below shielding structure 214 and not, as in the case without shielding structure 214 (see FIG. 1), in the vicinity of the base of semiconductor fin 302. This prevents, for example, an early electrical breakdown of field effect transistor 200 or voltage applied at drain electrode 218 from reaching through to gate electrode 210. Semiconductor fin 302 is depleted in the area which is adjacent to gate electrode 210. Without application of a gate voltage, field effect transistor 200 may be self-blocking, since the electron gas below semiconductor fin 302 may be depleted in the drift area. By applying a positive voltage at gate electrode 210, electrons may be accumulated in the area of semiconductor fin 302 which is adjacent to gate electrode 210. The electrons may flow from source electrode 202 through semiconductor fin 302 into the base of semiconductor fin 302 and from there into drift area 212 and move further through drift area 212 and substrate 216 into drain electrode 218.

In FIGS. 3A through 3K, further specific embodiments of vertical field effect transistor 200 illustrated in FIG. 2 are shown, the further layers or structures above drift area 212 not being illustrated.

The lateral and vertical extension of shielding structure 212 and their doping level are directed specifically to the application according to the degree of shielding of the space charge region below the base of semiconductor fin 302. Gate electrode 210 does not have to be formed completely between two semiconductor fins 302 here, in contrast to the conventional Fin-FET (FIG. 1), but rather, for example, on only one side wall of a semiconductor fin 302. This enables a reduced capacitance between gate electrode 210 and drain electrode 218. Alternatively, p-doped shielding structure may be formed after each second, third, etc. semiconductor fin 302. In FIG. 3A, a specific embodiment is illustrated in which a shielding structure 214 is formed after every second semiconductor fin 302 or each two semiconductor fins 302. A specific embodiment including a shielding structure 214 between each four semiconductor fins 302 is shown in FIG. 3B.

In various specific embodiments, a shielding structure 214 is formed on each side of semiconductor fin 302. Shielding structure 214 may be formed in this case between two semiconductor fins 302 (FIG. 3D) and/or a plurality of semiconductor fins may be formed between two adjacent shielding structures 214 (FIG. 3B).

Shielding structure 214 may be enclosed completely by drift area 212 (see FIG. 3C). Alternatively (see, for example, FIG. 3B) or additionally (see, for example, FIG. 3E), shielding structure 214 may include at least one area which is free of drift area 212. In other words: In various specific embodiments, buried shielding structures 214 and/or shielding structures 214 which are situated on the surface of drift area 212 may be provided. The position of buried shielding structures 214 is not restricted to the trenches between semiconductor fins 302. Alternatively or additionally, buried shielding structures 214 may be situated vertically below the base of semiconductor fin 302 (see, for example, FIG. 3F). In various specific embodiments, additional shielding structures may be formed to further increase the shielding effect. For example, the vertical distance of the shielding structure from the base of semiconductor fin 302 and/or the lateral extension of the shielding structure may vary in different specific embodiments (see, for example, FIGS. 3A through 3F). In other words, in various specific embodiments, shielding structure 214 has at least one first shielding structure 214 and one second shielding structure 214. First shielding structure 214 may extend vertically farther into drift area 212 in relation to semiconductor fin 302 or may be spaced apart further vertically from semiconductor fin 302 than second shielding structure 214. This enables application-specific shielding of the base of semiconductor fin 302 against electrical fields.

In various specific embodiments, shielding structures 214 may be formed in adjacent semiconductor fins 302, which are not used as vertical field effect transistors (see, for example, FIGS. 3G through 3I). In other words: In various specific embodiments, vertical field effect transistor 200 includes a drift area 212 including a first conductivity type; a first semiconductor fin 302 on or above drift area 212, and a second semiconductor fin 302, which is situated laterally adjacent to first semiconductor fin 302 on or above drift area 212. Laterally adjacent to at least one side wall of first semiconductor from 302, a source/drain electrode 202 is formed on or above drift area 212. A shielding structure 214 is formed laterally adjacent to the at least one side wall of first semiconductor fin 302, shielding structure 214 being situated in second semiconductor fin 302. Shielding structure 214 has a second conductivity type, which differs from the first conductivity type. Semiconductor fin 302 is electrically conductively connected to source/drain electrode 202. As an illustration, an additional semiconductor fin 302 may be provided, which is offset in the plane in relation to semiconductor fin 302, so that shielding structure 214 is situated in additional semiconductor fin 302.

FIG. 3G shows one specific embodiment of a vertical field effect transistor, in which a shielding structure 214, for example, in the form of a p-doped area, is formed in each third semiconductor fin 302. Alternatively, a shielding structure 214 may be formed in each second, fourth, etc., semiconductor fin 302. Distance A between one semiconductor fin 302 with shielding structure 214 and distance B between two semiconductor fins 302 without shielding structure 214 may be selected specifically by application, for example, to be identical or different. For example, distance A may be selected to be greater than distance B or distance B may be selected to be greater than distance A. The spatial extension of shielding structure 214 inside a semiconductor fin 302 in the plane of the drawing of FIG. 3G and/or in the direction of the base of semiconductor fin 302 may be selected specifically by application in various specific embodiments. Shielding structure 214 may optionally also be formed in entire semiconductor fin 302. Alternatively and/or additionally, shielding structure 214 may extend beyond the base of semiconductor fin 302 into drift area 212 (see, for example, FIG. 3H—right shielding structure 214). In various specific embodiments, effective shielding of the base of semiconductor fin 302 is implemented in that shielding structure 214 extends in the direction of or up to below the base of semiconductor fin 302. The shielding structure may be formed over the entire width (in the plane of the drawing) of semiconductor fin 302. In other words: shielding structure 214 may occupy or fill the entire width of a semiconductor fin 302. Alternatively or additionally (for example in other areas of semiconductor fin 302), shielding structure 214 may have a lateral extension which is less than the width of semiconductor fin 302. Shielding structure 214 may be configured in such a way that it has the same extension laterally as source/drain electrode 202 or may alternatively be configured in such a way that it has a lesser lateral extension than the extension of source/drain electrode 202 (see, for example, FIG. 3H). The variation of the lateral extension of shielding structure 214 offers the possibility of optimizing the component with respect to the shielding (may become better as the lateral extension becomes greater) or with respect to the on state resistance (may become less as the lateral extension becomes less).

The trench structures (the area between two adjacent semiconductor fins 302), which contain shielding structures 214 in various specific embodiments, may have a greater lateral extension than the trenches between individual semiconductor fins 302. In another specific embodiment, shielding structures 214 may also be embedded deep in drift area 212, for example, completely enclosed by drift area 212 and spaced apart from the base of semiconductor fin 302. Buried shielding structures 214 may be electrically connected to source/drain electrode 202 at another point of the vertical field effect transistor. The formation of the connections of the vertical field effect transistor takes place, for example, in a super cell structure (not shown).

In various specific embodiments, shielding structure 214 includes an area situated in drift area 212, which extends laterally in the direction of semiconductor fin 302. In various specific embodiments, shielding structure 214 may adjoin the base of semiconductor fin 302, for example, touch it (not shown).

Shielding structure 214 may be electrically conductively connected to semiconductor fin 302 and drift area 212. In various specific embodiments, shielding structures 214 are electrically conductively connected to source/drain electrode 202 (see, for example, FIG. 3B). Alternatively or additionally, shielding structures may be provided which are not (directly) electrically conductively connected to source/drain electrode 202 (see, for example, FIG. 3A). In this case, shielding structure 214 is at a floating electrical potential. In this case, the shielding effect of shielding structure 214 is retained. The structure including the floating shielding structure may no longer be used as a body diode for reverse operation, however. In various specific embodiments, all shielding structures 214 described above may also be designed in this floating form.

In various specific embodiments having a plurality of semiconductor fins 302, the semiconductor fins may have different widths. As an example, a (second) semiconductor fin with embedded shielding structure 214 may be formed wider than a (first) semiconductor fin without shielding structure.

In various specific embodiments, buried shielding structures 214 of the second conductivity type may be combined with additional areas 312 of the first conductivity type (see, for example, FIG. 3K). The depletion between buried p-areas of the shielding structures and thus the spreading of the current in drift area 212 may thus be set. It is accordingly possible to control or set the current density in this area. Second areas 312 may also be provided in all other specific embodiments.

In various specific embodiments, the semiconductor fin may be formed column-shaped, for example, spatially delimited in all spatial directions. In other words: the semiconductor fin may be a semiconductor column in various specific embodiments. The semiconductor column may have a square, rectangular, round, or hexagonal cross section of the column.

In various specific embodiments, the semiconductor fin may be formed having nonrectangular side walls, for example conical or pyramidal. The shielding structures shown above are also applicable to these structural variants. The buried shielding structures may be formed both in parallel and also perpendicularly and also at any arbitrary angle relatively laterally to the semiconductor fins.

FIG. 4 shows a flowchart of a method for forming a vertical field effect transistor according to various specific embodiments. In various specific embodiments, method 400 for forming a vertical field effect transistor 200 includes: forming 410 a drift area including a first conductivity type; forming 420 a semiconductor fin 302 on or above the drift area, a source/drain electrode being formed on or above drift area 212 laterally adjacent to at least one side wall of semiconductor fin 302; and forming 430 a shielding structure 214, which is situated laterally adjacent to the at least one side wall of semiconductor fin 302 in drift area 212, shielding structure 214 including a second conductivity type which differs from the first conductivity type, and shielding structure 214 being electrically conductively connected to semiconductor fin 302 and drift area 212.

Shielding structures 214 may be formed, for example, with the aid of ion implantation, for example, using aluminum ion implantation in the case of a SiC semiconductor fin or a SiC drift area or using magnesium ions in the case of a GaN semiconductor fin or a GaN drift area. To provide shielding structures embedded deep in the drift area without high-energy ion implantation, an additional trench 310 may be provided, in whose base the implantation takes place (see, for example, FIG. 3J)

In various specific embodiments, the shielding structures may be designed with the aid of so-called dead implantation. The shielding structures are designed by implanting an ion species, for example, argon ions, which does not cause doping in the SiC or GaN drift area. These shielding structures are no longer electrically conductive. Correspondingly, their shielding effect is retained, but they may no longer be used as the body diode for the reverse operation. Connecting such electrically nonconductive shielding structures to the source electrode is optional.

The specific embodiments described and shown in the figures are only selected as examples. Different specific embodiments may be combined with one another completely or with respect to individual features. One specific embodiment may also be supplemented by features of another specific embodiment.

Furthermore, described method steps may be carried out repeatedly and in a sequence other than that described. In particular, the present invention is not restricted to the specified method.

1-12. (canceled)

13. A vertical field effect transistor, comprising:
a drift area having a first conductivity type;
a semiconductor fin on or above the drift area;
a source/drain electrode on or above the drift area; and
a shielding structure, which is situated laterally adjacent to at least one side wall of the semiconductor fin in the drift area, the shielding structure having a second conductivity type, which differs from the first conductivity type;
wherein the semiconductor fin is electrically conductively connected to the source/drain electrode.

14. The vertical field effect transistor as recited in claim 13, wherein the source/drain electrode is formed laterally adjacent to at least one side wall of the semiconductor fin and is electrically conductively connected to the shielding structure.

15. The vertical field effect transistor as recited in claim 13, further comprising:
a gate electrode, which is formed adjacent to the at least one side wall of the semiconductor fin.

16. The vertical field effect transistor as recited in claim 13, wherein the drift area is n-conductive, and the shielding structure includes at least one p-conductive area.

17. The vertical field effect transistor as recited in claim 13, wherein the shielding structure includes an area situated in the drift area, which extends laterally in a direction of the semiconductor fin.

18. The vertical field effect transistor as recited in claim 13, wherein the shielding structure is completely enclosed by the drift area.

19. The vertical field effect transistor as recited in claim 13, wherein the shielding structure includes at least one area which is free of the drift area.

20. The vertical field effect transistor as recited in claim 13, wherein the shielding structure includes at least one first shielding structure and one second shielding structure, which are directly adjacent, and wherein at least one second semiconductor fin is formed laterally adjacent to the semiconductor fin on or above the drift area, the semiconductor fin and the at least one second semiconductor fin being situated laterally between the first shielding structure and the second shielding structure.

21. The vertical field effect transistor as recited in claim 13, wherein the shielding structure includes at least one first shielding structure and one second shielding structure, the first shielding structure extending vertically further into the drift area in relation to the semiconductor fin or being spaced apart vertically farther from the semiconductor fin, than the second shielding structure.

22. The vertical field effect transistor as recited in claim 13, further comprising:
at least one additional area, which has the first conductivity type and is formed laterally adjacent to the shielding structure.

23. The vertical field effect transistor, comprising:
a drift area having a first conductivity type;
a first semiconductor fin on or above the drift area and a second semiconductor fin, which is situated laterally adjacent to the first semiconductor fin on or above the drift area;
a source/drain electrode formed on or above the drift area laterally adjacent to at least one side wall of the first semiconductor fin; and
a shielding structure, which is formed laterally adjacent to the at least one side wall of the first semiconductor fin, the shielding structure being situated in the second semiconductor fin, and the shielding structure having a second conductivity type, which differs from the first conductivity type, and the semiconductor fin being electrically conductively connected to the source/drain electrode.

24. A method for forming a vertical field effect transistor, the method comprising the following steps:
forming a drift area having a first conductivity type;
forming a semiconductor fin on or above the drift area, a source/drain electrode being formed on or above the drift area laterally adjacent to at least one side wall of the semiconductor fin; and
forming a shielding structure, which is situated laterally adjacent to the at least one side wall of the semiconductor fin in the drift area, the shielding structure having a second conductivity type, which differs from the first conductivity type, and the semiconductor fin being electrically conductively connected to the source/drain electrode.
